(19) United States
(12) Patent Application Publication
(10) Pub. No.: US 2026/0123205 A1
(43) Pub. Date: Apr. 30, 2026

(54) DISPLAY PANEL AND DISPLAY DEVICE

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/369,230

(22) Filed: Oct. 26, 2025

(30) Foreign Application Priority Data
Oct. 31, 2024 (CN) 202411548453.8

(51) Int. Cl. H10K 59/127; H10K 59/131; H10K 59/80

(52) U.S. Cl. CPC H10K 59/1275; H10K 59/131; H10K 59/873

(57) ABSTRACT

A display panel and a display device. The display panel includes a glass substrate, multiple light-emitting units, multiple first connecting portions, a silicon-based drive substrate, and multiple conductive composite layers. The glass substrate defines multiple first conductive through holes extending from a first surface to a second surface. Each first connecting portion is electrically connected to a corresponding anode via a corresponding first conductive through hole. The silicon-based drive substrate includes multiple first connecting electrodes, each at least partially embedded within a corresponding first conductive through hole. Each conductive composite layer is disposed between a corresponding first connecting electrode and a corresponding first connecting portion. The first connecting electrode is electrically connected to the first connecting portion through the conductive composite layer. The conductive composite layer can break the electrical connection between the first connecting electrode and the first connecting portion under laser irradiation at a predetermined wavelength band.

### CROSS-REFERENCE TO RELATED APPLICATIONS

The present application claims priority of Chinese Patent Application No. 202411548453.8, filed on Oct. 31, 2024, the entire contents of which are hereby incorporated by reference in their entirety.

### TECHNICAL FIELD

The present disclosure relates to the field of display technologies, and in particular to a display panel and a display device.

### BACKGROUND

A monocrystalline silicon-driven backplane utilizes semiconductor devices fabricated via complementary metal-oxide-semiconductor (CMOS) processes as driving units. Compared to conventional active-matrix organic light-emitting diode (AMOLED) panels employing amorphous silicon, microcrystalline silicon, or low-temperature polycrystalline silicon (LTPS) thin-film transistors as backplanes, the monocrystalline silicon-driven backplane exhibits superior carrier mobility. Consequently, silicon-based organic light-emitting diode (OLED) display panels represent the most advanced display technology currently employed in augmented reality (AR) and virtual reality (VR) applications, offering unparalleled performance.

Currently, the silicon-based OLED displays integrate traditionally external display driver chips directly into the silicon-driven backplane. The fabrication process involves vapor-deposition of OLED light-emitting layers onto the silicon substrate. Specifically, this entails deposition to form an anode, formation of a pixel definition layer (PDL), and deposition to form an organic emissive layer and a cathode. This approach enables the creation of ultrafine pixel structures with resolutions exceeding retinal-level acuity, delivering high-resolution imagery, high integration density, low power consumption, compact form factors, and lightweight designs.

However, direct vapor-deposition of the OLED light-emitting layers onto silicon-driven substrates may easily affect the silicon-based drive circuits, causing damage to the drive circuits and rendering them unusable, thereby increasing costs.

### SUMMARY OF THE DISCLOSURE

The present disclosure provides a display panel, comprising:
a glass substrate, comprising a first surface and a second surface that are opposite each other, and defining a plurality of conductive through holes extending from the first surface to the second surface; wherein the plurality of conductive through holes comprise a plurality of first conductive through holes;
a plurality of light-emitting units, disposed on the first surface of the glass substrate; wherein each light-emitting unit comprises an anode, an organic light-emitting layer, and a cathode that are stacked in sequence along a direction away from the glass substrate;
a plurality of first connecting portions; wherein each first connecting portion is disposed within a corresponding first conductive through hole; the first connecting portion is electrically connected to a corresponding anode through the corresponding first conductive through hole;
a silicon-based drive substrate, disposed on a side with the second surface of the glass substrate, and comprising a plurality of first connecting electrodes; wherein each first connecting electrode is at least partially embedded within a corresponding first conductive through hole; and
a plurality of conductive composite layers; wherein each conductive composite layer is disposed between a corresponding first connecting electrode and a corresponding first connecting portion; the corresponding first connecting electrode is electrically connected to the corresponding first connecting portion via the conductive composite layer; the conductive composite layer is capable of breaking an electrical connection between the corresponding first connecting electrode and the corresponding first connecting portion under irradiation of a laser light in a predetermined wavelength band.

The present disclosure further provides a display device, comprising the display panel as above.

The present disclosure further provides a display panel, comprising:
a glass substrate, comprising a first surface and a second surface that are opposite each other, and defining a plurality of first conductive through holes extending from the first surface to the second surface;
a plurality of light-emitting units, disposed on the first surface of the glass substrate; and
a silicon-based drive substrate, disposed on a side with the second surface of the glass substrate, and comprising a plurality of first connecting electrodes;
wherein for each first conductive through hole, a corresponding light-emitting unit is arranged covering the first conductive through hole, a first connecting portion is arranged in the first conductive through hole and electrically connected to the corresponding light-emitting unit, and a corresponding first connecting electrode is at least partially embedded within the first conductive through hole;
a conductive composite layer is arranged between the corresponding first connecting electrode and the first connecting portion; the corresponding first connecting electrode is electrically connected to the first connecting portion via the conductive composite layer; the conductive composite layer is capable of breaking an electrical connection between the corresponding first connecting electrode and the first connecting portion under irradiation of a laser light in a predetermined wavelength band.

### BRIEF DESCRIPTION OF THE DRAWINGS

FIG. 1 is a structural schematic view of a display panel according to some embodiments of the present disclosure.

FIG. 2 is a partial enlarged view of area A circumscribed in FIG. 1.

FIG. 3 is a partial enlarged view of area B circumscribed in FIG. 2.

FIG. 4 is a structural schematic view of foamed gel particles after expansion in the structure shown in FIG. 3.

FIG. 5 is a structural schematic view of the display device according to some embodiments of the present disclosure.

### REFERENCE NUMERALS

100—Display panel; 1—Glass substrate; 2—Light-emitting unit; 3—Pixel definition layer; 4—First connecting portion; 5—Silicon-based drive substrate; 6—Conductive composite layer; 7—Second connecting portion; 8—Encapsulation layer; 11—First surface; 12—Second surface; 13—Conductive through hole; 21—Anode; 22—Organic light-emitting layer; 23—Cathode; 51—First connecting electrode; 52—Silicon substrate; 53—Drive circuit; 54—Protective layer; 55—Second connecting electrode; 61—Excitation member; 62—Response member; 131—First conductive through hole; 132—Second conductive through hole; 611—Aerogel layer; 621—Composite repair layer; 6111—Conductive aerogel layer; 6211—Conductive particles; 6212—Foamed gel particles; 6213—Base structure.

### DETAILED DESCRIPTION

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first,” “second,” and “third” used in the present disclosure are for descriptive purposes only and should not be understood as indicating or implying relative importance or the number of technical features indicated. Therefore, features defined with “first,” “second,” or “third” may explicitly or implicitly include at least one of the features indicated. In the description of the present disclosure, “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have,” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

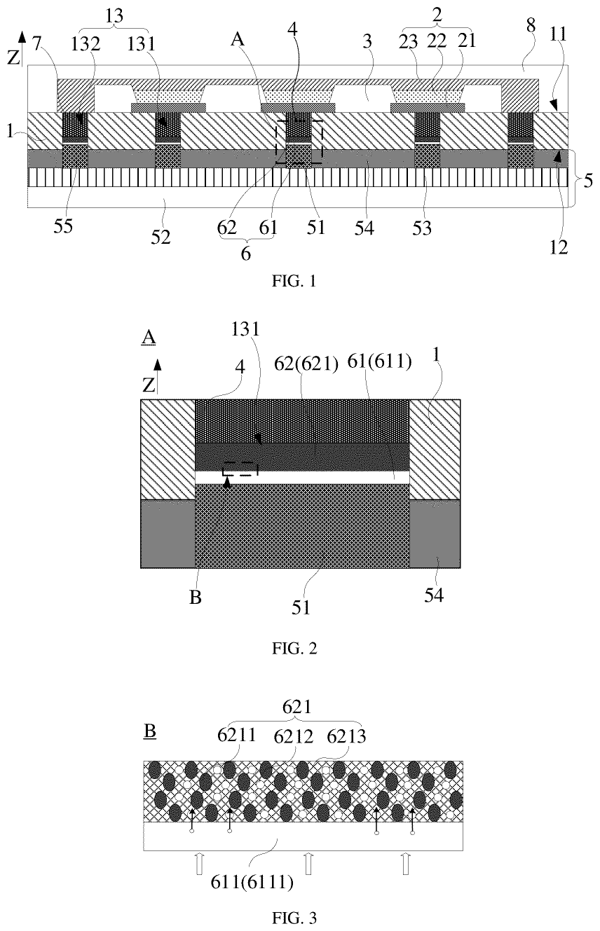

Referring to FIG. 1, FIG. 1 is a structural schematic view of a display panel according to some embodiments of the present disclosure. The present disclosure provides a display panel, which may be an OLED display panel. The display panel may include a glass substrate 1, multiple light-emitting units 2, multiple first connecting portions 4, a silicon-based drive substrate 5, and multiple conductive composite layers 6.

The glass substrate 1 includes a first surface 11 and a second surface 12, and the glass substrate 1 defines multiple conductive through holes 13 extending from the first surface 11 to the second surface 12. The multiple conductive through holes 13 may include multiple first conductive through holes 131.

The multiple light-emitting units 2 are disposed on the first surface 11 of the glass substrate 1; each light-emitting unit 2 includes an anode 21, an organic light-emitting layer 22, and a cathode 23 stacked in sequence in a direction away from the glass substrate 1. Specifically, the first surface 11 of the glass substrate 1 is further arranged with a pixel definition layer 3, which protrudes from the glass substrate 1 and encloses to define multiple pixel accommodation regions (not shown); the multiple light-emitting units 2 are respectively disposed within the multiple pixel accommodation regions. The multiple pixel accommodation regions correspond to the multiple first conductive through holes 131 in a one-to-one correspondence.

The anode 21 is disposed on a surface of the glass substrate 1 exposed through the pixel accommodation region, and the pixel definition layer 3 covers an edge of the anode 21 to prevent the anodes 21 of adjacent light-emitting units 2 from contacting each other, thereby avoiding signal crosstalk. The organic light-emitting layer 22 is disposed on a surface of the anode 21 away from the glass substrate 1, and the cathode 23 is disposed on a surface of the organic light-emitting layer 22 away from the anode 21 and covers the organic light-emitting layers 22 of multiple light-emitting units 2 to form a common cathode across the entire surface. The anode 21 and cathode 23 respectively transmit anode drive signals and cathode drive signals to the organic light-emitting layer 22 to drive the organic light-emitting layer 22, thereby emitting light.

In some embodiments, the light-emitting units 2 may include light-emitting units 2 of different light-emitting colors, such as red light-emitting units, green light-emitting units, and blue light-emitting units, to achieve color display. Specifically, the light-emitting color of the light-emitting unit 2 is determined by the light-emitting color of the organic light-emitting layer 22. Alternatively, in other embodiments, the light-emitting units 2 may be of the same light-emitting color, such as white, red, green, blue, or other colors, which may be set according to actual needs; for example, the light-emitting unit 2 is white, and grayscale display is achieved by controlling the brightness of the light-emitting unit 2, and a color-blocking layer may be arranged above the light-emitting unit 2 to achieve color display. For example, when the light-emitting unit 2 is blue, a red quantum dot layer may be arranged above some of the light-emitting units 2, and a green quantum dot layer may be arranged above some of the light-emitting units 2, thereby achieving color display.

The multiple first connecting portions 4 are disposed on the second surface 12 of the glass substrate 1, and each first connecting portion 4 is disposed within a corresponding first conductive through hole 131; each first connecting portion 4 is electrically connected to the corresponding anode 21 via the first conductive through hole 131, thereby transmitting an anode drive signal to the anode 21 of the corresponding light-emitting unit 2 through the first conductive through hole 131.

The silicon-based drive substrate 5 is disposed on a side with the second surface 12 of the glass substrate 1; the silicon-based drive substrate 5 may further include multiple first connecting electrodes 51, each connecting electrode being at least partially embedded within the corresponding first conductive through hole 131 and electrically connected to the corresponding first connecting portion 4, for controlling the light emission of the corresponding light-emitting unit 2 corresponding to the first connecting portion 4. Specifically, the first connecting electrode 51 is spaced apart from a side wall of the corresponding first conductive through hole 131.

Specifically, the silicon-based drive substrate 5 may further include a silicon substrate 52 and a drive circuit 53 that are stacked; where the silicon substrate 52 refers to a base plate made of single-crystal silicon material; the drive circuit 53 is electrically connected to the multiple first connecting electrodes 51 and is configured to transmit an anode drive signal to the anode 21 through the first connecting portion 4. Specifically, the drive circuit 53 includes an active drive circuit 53 integrated on the single-crystal silicon substrate 52 using CMOS process; it may specifically include multiple “3T1C” structures (three thin-film transistors and one capacitor) to achieve independent control of each light-emitting unit 2 and high-quality display.

The silicon-based drive substrate 5 may further include a display control circuit (not shown) electrically connected to the drive circuit 53, which is configured to control the light-emitting units 2 for display via the drive circuit 53; where the display control circuit may be an integrated circuit (IC) integrated on the silicon-based drive substrate 5.

By arranging the light-emitting units 2 and the first connecting portions 4 on the opposite surfaces of the glass substrate 1, and electrically connecting the first connecting portions 4 to the anodes 21 of the corresponding light-emitting units 2 through the first conductive through holes 131, the light-emitting units 2 are electrically coupled to the silicon-based drive substrate 5, enabling the silicon-based drive substrate 5 to drive the light-emitting units 2 to emit light. In this way, it is not necessary to directly fabricate the light-emitting units 2 on the silicon-based drive substrate 5, thereby avoiding the issue of damaging the pixel drive circuit 53 caused by directly fabricating the light-emitting units 2 on the silicon-based drive substrate 5, which could lead to a decrease in product yield. Additionally, glass through hole technology offers superior high-frequency electrical characteristics, low cost, a simple manufacturing process, and excellent mechanical stability compared to silicon through hole technology.

As shown in FIG. 1, the conductive composite layer 6 is disposed between the corresponding first connecting electrode 51 and the corresponding first connecting portion 4. The first connecting electrode 51 may be electrically connected to the first connecting portion 4 through the conductive composite layer 6 to transmit the anode drive signal to the anode of the corresponding sub-pixel. The conductive composite layer 6 can break the electrical connection between the first connecting electrode 51 and the first connecting portion 4 under laser irradiation at a predetermined wavelength band. Specifically, the method by which the conductive composite layer 6 breaks the electrical connection may be by altering its internal structure to change its electrical conductivity; or by causing the conductive composite layer 6 to deform, thereby causing the conductive composite layer 6 to lose contact with the first connecting electrode 51 and/or the first connecting portion 4 to break the electrical connection.

By arranging the conductive composite layer 6 between the first connecting electrode 51 and the first connecting portion 4, the first connecting electrode 51 and the first connecting portion 4 are electrically connected, while the conductive composite layer 6 can further break the electrical connection between the first connecting electrode 51 and the first connecting portion 4 under laser irradiation at a predetermined wavelength band. In this way, when highlight repair is required for a pixel, laser irradiation can be applied to the conductive composite layer 6 corresponding to that pixel, causing the conductive composite layer 6 to break the electrical connection between the first connecting electrode 51 and the first connecting portion 4, thereby causing the pixel to become a permanently black dark spot, and thus achieving highlight repair.

Referring to FIG. 2, FIG. 2 is a partial enlarged view of area A circumscribed in FIG. 1. In a specific embodiment, the conductive composite layer 6 may include an excitation member 61 and a response member 62; where the excitation member 61 is configured to provide excitation, and the first connecting electrode 51 is electrically connected to the first connecting portion 4 via the response member 62; the response member 62 is in contact with at least one of the first connecting electrode 51 and the first connecting portion 4.

Specifically, the excitation member 61 can provide excitation under laser irradiation at a predetermined wavelength band; in response to the excitation provided by the excitation member 61, the response member 62 can disconnect the electrical connection between the first connecting electrode 51 and the first connecting portion 4. By enabling the response member 62, which provides the electrical connection, to disconnect the electrical connection between the first connecting electrode 51 and the first connecting portion 4 under laser irradiation at a predetermined wavelength band, when highlight repair is required for a pixel, laser irradiation of the conductive composite layer 6 corresponding to the pixel can cause the conductive composite layer 6 to disconnect the electrical connection between the first connecting electrode 51 and the first connecting portion 4, thereby preventing the silicon-based drive substrate 5 from transmitting an anode drive signal to the pixel, causing the pixel to become a permanently black dark spot, and thus achieving highlight repair.

Specifically, the response member 62 may break the electrical connection by altering its internal structure to change its conductivity, preventing the first connecting electrode 51 from transmitting the anode drive signal to the first connecting portion 4 through the response member 62; or by causing the response member 62 to deform, causing it to lose contact with the first connecting electrode 51 and/or the first connecting portion 4 to disconnect the electrical connection.

The following embodiments of the present disclosure are explained using the example of altering the internal structure of the response member 62 to change its electrical conductivity.

Specifically, the excitation member 61 may include an aerogel layer 611; the aerogel layer 611 can undergo structural degradation under laser irradiation in a predetermined wavelength band to generate gas, which is configured to excite the response member 62. The laser may be an infrared laser, with a predetermined wavelength band of 700 nm to 1 mm; specifically, the predetermined wavelength band may be any of the ranges of 700 nm to 800 nm, 800 nm to 1000 nm, 1000 nm to 2000 nm, or 2000 nm to 1 mm. In some embodiments, the laser may be a far-infrared laser, with a predetermined wavelength band of 10,000 nm to 1 mm.

Of course, in other embodiments, the laser configured to irradiate the aerogel layer 611 may be an ultraviolet laser, with a preset wavelength band of 370 nm to 405 nm.

The response member 62 may include a composite repair layer 621, which is configured to provide an electrical connection between the first connecting electrode 51 and the first connecting portion 4 or disconnects the electrical connection under the excitation of gas. Specifically, as shown in FIG. 3, FIG. 3 is a partial enlarged view of area B circumscribed in FIG. 2, The composite repair layer 621 may include uniformly dispersed multiple conductive particles 6211 and multiple foamed gel particles 6212; the composite repair layer 621 has a multi-porous structure, and the multiple conductive particles 6211 and the multiple foamed gel particles 6212 are uniformly mixed in the multi-porous structure.

Specifically, the uniformly dispersed multiple conductive particles 6211 enable the composite repair layer 621 to have conductive capability, and the first connecting electrode 51 is electrically connected to the corresponding first connecting portion 4 at least partially through the uniformly dispersed multiple conductive particles 6211. The gas generated by the aerogel can excite the multiple foamed gel particles 6212; specifically, the multiple foamed gel particles 6212 can absorb the gas generated by the aerogel layer 611.

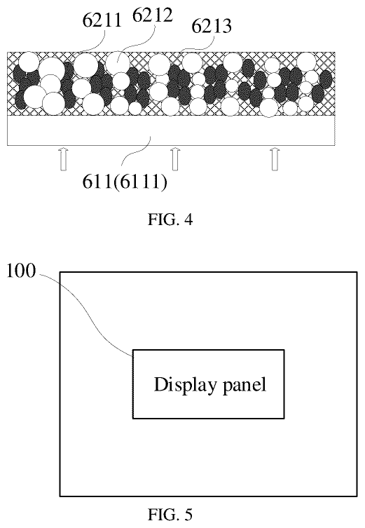

Referring to FIGS. 3 and 4, FIG. 4 is a structural schematic view of foamed gel particles after expansion in the structure shown in FIG. 3. In response to the foamed gel particles 6212 absorbing the gas generated by the aerogel layer 611, the foamed gel particles 6212 undergo foaming nucleation growth, causing their volume to expand and compress the multiple conductive particles 6211, causing the multiple conductive particles 6211 to agglomerate, thereby disconnecting the electrical connection between the first connecting electrode 51 and the corresponding first connecting portion 4.

In this way, when highlight repair is required for a pixel, laser irradiation of the aerogel layer 611 causes the aerogel layer 611 to generate gas, which excites the foamed gel particles 6212 in the composite repair layer 621. This causes the foamed gel particles 6212 to absorb gas and undergo foaming nucleation growth, causing the volume of the foamed gel particles 6212 to rapidly expand, thereby compressing the internal voids of the composite repair layer 621, causing the originally uniformly dispersed multiple conductive particles 6211 to agglomerate and lose uniformity; when the multiple conductive particles 6211 agglomerate to a certain extent, the composite repair layer 621 loses its conductivity, thereby breaking the electrical connection between the first connecting electrode 51 and the corresponding first connecting portion 4. As a result, the silicon-based drive substrate 5 cannot transmit the anode drive signal to the pixel, causing the pixel to become a permanently black dark spot, thereby achieving highlight repair.

As shown in FIG. 3, in a specific embodiment, the composite repair layer 621 may further include a base structure 6213, which forms the multi-pore structure within the composite repair layer 621, enabling the multiple conductive particles 6211 and multiple foamed gel particles 6212 to be uniformly distributed within the pores formed by the base structure 6213, and enabling the conductive particles 6211 to move and agglomerate within the pores under the compression of the expanded foamed gel particles 6212. Specifically, the multiple conductive particles 6211 and the multiple foamed gel particles 6212 are dispersed on a surface of the base structure 6213.

Specifically, the base structure 6213 may be a fiber felt; the fiber felt may be prepared by an electrostatic spinning method. Specifically, a polymer solution or melt may be sprayed into fine droplets under the application of a high-voltage electrostatic field, and then stretched into fibers under the action of the electric field force. This method may produce continuous fibers with diameters ranging from tens of nanometers to hundreds of nanometers, featuring high surface area, high porosity, and excellent mechanical properties. The highly elastic fiber felt facilitates the movement of conductive particles 6211 and foamed gel particles 6212 within the pores. The material of the fiber felt may be any one or a combination of the following: polyester, polyamide, polyvinyl alcohol, polyacrylonitrile, polyurethane, or poly(p-phenylene terephthalamide).

Of course, in other embodiments, the base structure 6213 may be a porous membrane layer, such as a polyimide porous film.

The conductive particles 6211 may include conductive graphite particles to impart good conductivity and dispersion properties to the conductive particles 6211. The foamed gel particles 6212 may include polyurethane soft foam gel materials and catalytic phase materials; where the polyurethane soft foam gel materials can undergo foaming conversion at room temperature in the presence of the catalytic phase materials to form polyurethane foam materials. Specifically, the catalytic phase materials may be amine-based or oxide-based catalysts.

Referring further to FIG. 3, the aerogel layer 611 may be a conductive aerogel layer 6111; the conductive aerogel layer 6111 is stacked along a thickness direction Y of the display panel with the composite repair layer 621. The conductive aerogel layer 6111 may be prepared by doping conductive fillers into the aerogel; the conductive fillers may specifically be carbon nanotubes, graphite powder, metal nanoparticles, etc., and the aerogel may be silane aerogel or siloxane aerogel.

It can be understood that by stacking the conductive aerogel layer 6111 with the composite repair layer 621, the different positions of the composite repair layer 621 can uniformly absorb the gas generated by the conductive aerogel layer 6111, ensuring that the changes in conductivity at different positions of the composite repair layer 621 remain consistent. This may prevent the conductive composite layer 6 from failing in repairing bright pixels caused by the inconsistent foaming degree of the foamed gel particles 6212 at different positions within the composite repair layer 621.

Specifically, the composite repair layer 621 may be in contact with one of the first connecting electrode 51 and the first connecting portion 4, while the conductive aerogel layer 6111 may be in contact with the other of the first connecting electrode 51 and the first connecting portion 4. The conductive aerogel layer 6111 is in contact with the composite repair layer 621, and the conductive aerogel layer 6111 is electrically conductive. The first connecting electrode 51 is electrically connected to the first connecting portion 4 through the conductive aerogel layer 6111 and the composite repair layer 621.

Specifically, as shown in FIG. 2, the conductive aerogel layer 6111 may be disposed on a surface of the first connecting electrode 51 facing the glass substrate 1; the composite repair layer 621 may be disposed on a surface of the first connecting portion 4 facing the silicon-based drive substrate 5. In response to the multiple foam gel particles 6212 in the composite repair layer 621 absorbing the gas generated by the conductive aerogel layer 6111, the multiple conductive particles 6211 in the composite repair layer 621 are squeezed and agglomerated under the action of the expanded foamed gel particles 6212, causing the composite repair layer 621 to lose its conductivity, thereby disconnecting the electrical connection between the conductive aerogel layer 6111 and the first connecting portion 4 and thus achieving highlight repair.

Of course, in some embodiments, the conductive aerogel layer 6111 may be disposed on a surface of the first connecting portion 4 facing the silicon-based drive substrate 5; the composite repair layer 621 may be disposed on a surface of the first connecting electrode 51 facing the glass substrate 1. In response to the multiple foamed gel particles 6212 in the composite repair layer 621 absorbing the gas generated by the conductive aerogel layer 6111, the multiple conductive particles 6211 in the composite repair layer 621 are squeezed and agglomerated under the action of the expanded foamed gel particles 6212, causing the composite repair layer 621 to lose its conductivity, thereby disconnecting the electrical connection between the conductive aerogel layer 6111 and the first connecting electrode 51 and thus achieving highlight repair.

Of course, in other embodiments, the composite repair layer 621 may be separately contacted with the first connecting electrode 51 and the first connecting portion 4, and the first connecting electrode 51 may be directly electrically connected to the first connecting portion 4 through the conductive aerogel layer 6111; in this way, the excitation member 61 may be a non-conductive aerogel layer 611, thereby reducing manufacturing costs.

The silicon-based drive substrate 5 may further include a protective layer 54 disposed on a side close to the glass substrate 1, with at least a portion of the first connecting electrode 51 embedded within the protective layer 54. The protective layer 54 is configured to protect the drive circuit 53 from corrosion by external moisture. The material of the protective layer 54 may specifically be an inorganic insulating material such as silicon dioxide, silicon nitride, or silicon oxide.

Referring to FIG. 1, in a specific embodiment, the conductive through holes 13 may further include multiple second conductive through holes 132 arranged around a periphery of the multiple first conductive through holes 131; the display panel may further include multiple second connecting portions 7 at least partially disposed within the second conductive through holes 132, where each second connecting portion 7 is electrically connected to the cathode 23 via the corresponding second conductive through hole 132, for transmitting a cathode drive signal to the cathode 23 of the light-emitting unit 2 through the second conductive through hole 132. The silicon-based drive substrate 5 may further include multiple second connecting electrodes 55, each of which is aligned and connected with a corresponding second connecting portion 7 in a one-to-one correspondence. The silicon-based drive substrate 5 can transmit the cathode drive signals to the cathode 23 through the second connecting electrodes 55 and the second connecting portions 7 to control the emission of light from the light-emitting units 2.

As shown in FIG. 1, in a specific embodiment, the glass substrate 1 is further arranged with an encapsulation layer 8 for protecting the light-emitting units 2 on the glass substrate 1, isolating external water and oxygen, and preventing the light-emitting units 2 from malfunctioning caused by the invasion of the water and oxygen. Specifically, the encapsulation layer 8 covers a surface of the cathode 23 away from the anode 21 and overlaps the surface of the glass substrate 1 not covered by the light-emitting units 2.

The present disclosure provides a display panel and a display device. The display panel includes a glass substrate 1, multiple light-emitting units 2, multiple first connecting portions 4, a silicon-based drive substrate 5, and multiple conductive composite layers 6. The glass substrate 1 includes a first surface 11 and a second surface 12 that are opposite each other, and the glass substrate 1 defines multiple conductive through holes 13 extending from the first surface 11 to the second surface 12; the multiple conductive through holes 13 include multiple first conductive through holes 131. The multiple light-emitting units 2 are disposed on the first surface 11 of the glass substrate 1; each light-emitting unit 2 includes an anode 21, an organic light-emitting layer 22, and a cathode 23 stacked in sequence in a direction away from the glass substrate 1. Each first connecting portion 4 is disposed within a corresponding first conductive through hole 131; the first connecting portion 4 is electrically connected to a corresponding anode 21 through the corresponding first conductive through hole 131. The silicon-based drive substrate 5 is disposed on a side with the second surface 12 of the glass substrate 1, including multiple first connecting electrodes 51; each first connecting electrode 51 is at least partially embedded within a corresponding first conductive through hole 131. Each conductive composite layer 6 is disposed between a corresponding first connecting electrode 51 and a corresponding first connecting portion 4; the corresponding first connecting electrode 51 is electrically connected to the corresponding first connecting portion 4 via the conductive composite layer 6; the conductive composite layer 6 is capable of breaking an electrical connection between the corresponding first connecting electrode 51 and the corresponding first connecting portion 4 under irradiation of a laser light in a predetermined wavelength band. By disposing the light-emitting units 2 and the first connecting portions 4 on opposite surfaces of the glass substrate 1, and electrically connecting the first connecting portions 4 to the anodes 21 of the corresponding light-emitting units 2 through the first conductive through holes 131, the light-emitting units 2 are electrically coupled to the silicon-based drive substrate 5, enabling the silicon-based drive substrate 5 to drive the light-emitting units 2 to emit light. In this way, it is not necessary to directly fabricate the light-emitting units 2 on the silicon-based drive substrate 5, thereby avoiding the issue of damaging the pixel drive circuit 53 caused by directly fabricating the light-emitting units 2 on the silicon-based drive substrate 5, which could lead to a decrease in product yield. Additionally, by arranging the conductive composite layer 6 between the first connecting electrode 51 and the first connecting portion 4, the first connecting electrode 51 and the first connecting portion 4 are electrically connected, while the conductive composite layer 6 can further break the electrical connection between the first connecting electrode 51 and the first connecting portion 4 under laser irradiation at a predetermined wavelength band. In this way, when highlight repair is required for a pixel, laser irradiation can be applied to the conductive composite layer 6 corresponding to that pixel, causing the conductive composite layer 6 to break the electrical connection between the first connecting electrode 51 and the first connecting portion 4, thereby preventing the silicon-based drive substrate 5 from transmitting an anode drive signal to the pixel, causing the pixel to become a permanently black dark spot, and thus achieving highlight repair.

Referring to FIG. 5, FIG. 5 is a structural schematic view of the display device according to some embodiments of the present disclosure. The present disclosure further provides a display device for displaying images. The display device includes the display panel 100 described in any of the above embodiments. The display device may avoid damaging the pixel drive circuit by directly forming light-emitting units on the silicon-based drive substrate. Additionally, when highlight repair is required for a pixel, the display device prevents the silicon-based drive substrate from transmitting an anode drive signal to the pixel, causing the pixel to become a permanently black dark spot, thereby achieving highlight repair.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A display panel, comprising:
a glass substrate, comprising a first surface and a second surface that are opposite each other, and defining a plurality of conductive through holes extending from the first surface to the second surface; wherein the plurality of conductive through holes comprise a plurality of first conductive through holes;
a plurality of light-emitting units, disposed on the first surface of the glass substrate; wherein each light-emitting unit comprises an anode, an organic light-emitting layer, and a cathode that are stacked in sequence along a direction away from the glass substrate;
a plurality of first connecting portions; wherein each first connecting portion is disposed within a corresponding first conductive through hole; the first connecting portion is electrically connected to a corresponding anode through the corresponding first conductive through hole;
a silicon-based drive substrate, disposed on a side with the second surface of the glass substrate, and comprising a plurality of first connecting electrodes; wherein each first connecting electrode is at least partially embedded within a corresponding first conductive through hole; and
a plurality of conductive composite layers; wherein each conductive composite layer is disposed between a corresponding first connecting electrode and a corresponding first connecting portion; the corresponding first connecting electrode is electrically connected to the corresponding first connecting portion via the conductive composite layer; the conductive composite layer is capable of breaking an electrical connection between the corresponding first connecting electrode and the corresponding first connecting portion under irradiation of a laser light in a predetermined wavelength band.

2. The display panel according to claim 1, wherein the conductive composite layer comprises an excitation member and a response member; the corresponding first connecting electrode is electrically connected to the corresponding first connecting portion via the response member;
the excitation member is configured to provide excitation under the irradiation of the laser light in the predetermined wavelength band; and in response to the excitation provided by the excitation member, the response member is configured to break the electrical connection between the corresponding first connecting electrode and the corresponding first connecting portion.

3. The display panel according to claim 2, wherein the response member is configured to break the electrical connection by deformation, causing the response member to lose contact with at least one of the corresponding first connecting electrode and the corresponding first connecting portion.

4. The display panel according to claim 2, wherein the response member is configured to break the electrical connection by altering an internal structure of the response member to change conductivity.

5. The display panel according to claim 4, wherein the excitation member comprises an aerogel layer; the aerogel layer is capable of generating gas under the irradiation of the laser light in the predetermined wavelength band;
the response member comprises a composite repair layer; the composite repair layer comprises a plurality of conductive particles and a plurality of foamed gel particles that are uniformly dispersed; the corresponding first connecting electrode is electrically connected to the corresponding first connecting portion at least partially through the plurality of conductive particles that are uniformly dispersed; the plurality of foamed gel particles are capable of absorbing the gas generated by the aerogel layer;
in response to the plurality of foamed gel particles absorbing the gas generated by the aerogel layer, the plurality of foamed gel particles undergo foaming nucleation growth, causing volume of the plurality of foamed gel particles to expand and compressing the plurality of conductive particles, for causing the plurality of conductive particles to agglomerate and break the electrical connection between the corresponding first connecting electrode and the corresponding first connecting portion.

6. The display panel according to claim 5, wherein the aerogel layer is a conductive aerogel layer; the conductive aerogel layer is stacked along a thickness direction of the display panel with the composite repair layer; the corresponding first connecting electrode is electrically connected to the corresponding first connecting portion through the conductive aerogel layer and the composite repair layer.

7. The display panel according to claim 6, wherein the conductive aerogel layer is disposed on a surface of the corresponding first connecting electrode facing the glass substrate; the composite repair layer is disposed on a surface of the corresponding first connecting portion facing the silicon-based drive substrate; in response to the composite repair layer absorbing the gas generated by the conductive aerogel layer, the composite repair layer breaks the electrical connection between the conductive aerogel layer and the corresponding first connecting portion.

8. The display panel according to claim 6, wherein the conductive aerogel layer is disposed on a surface of the corresponding first connecting portion facing the silicon-based drive substrate; the composite repair layer is disposed on a surface of the corresponding first connecting electrode facing the glass substrate; in response to the composite repair layer absorbing the gas generated by the conductive aerogel layer, the composite repair layer breaks the electrical connection between the conductive aerogel layer and the corresponding first connecting electrode.

9. The display panel according to claim 6, wherein the composite repair layer is separately contacted with the corresponding first connecting electrode and the corresponding first connecting portion, and the corresponding first connecting electrode is directly electrically connected to the corresponding first connecting portion through the conductive aerogel layer; the excitation member is a non-conductive aerogel layer.

10. The display panel according to claim 5, wherein the composite repair layer further comprises a base structure, and the plurality of conductive particles and the plurality of foamed gel particles are dispersed on a surface of the base structure.

11. The display panel according to claim 10, wherein the base structure is a fiber felt; a material of the fiber felt is any one or a combination of: polyester, polyamide, polyvinyl alcohol, polyacrylonitrile, polyurethane, or poly(p-phenylene terephthalamide).

12. The display panel according to claim 10, wherein the plurality of conductive particles comprise conductive graphite particles.

13. The display panel according to claim 10, wherein the plurality of foamed gel particles comprise a polyurethane soft foam gel material and a catalytic phase material.

14. The display panel according to claim 1, wherein the laser light is a far-infrared laser, with the predetermined wavelength band of 10,000 nm to 1 mm.

15. The display panel according to claim 1, wherein the plurality of conductive through holes further comprise a plurality of second conductive through holes arranged around a periphery of the plurality of first conductive through holes; the display panel further comprises a plurality of second connecting portions at least partially disposed within the second conductive through holes, where each second connecting portion is electrically connected to the cathode via a corresponding second conductive through hole; the silicon-based drive substrate further comprises a plurality of second connecting electrodes, where each second connecting electrode is aligned and connected with a corresponding second connecting portion.

16. The display panel according to claim 1, wherein the glass substrate is further arranged with an encapsulation layer; the encapsulation layer covers a surface of the cathode away from the anode and overlaps a surface of the glass substrate not covered by the plurality of light-emitting units.

17. A display device, comprising a display panel; wherein the display panel comprises:
a glass substrate, comprising a first surface and a second surface that are opposite each other, and defining a plurality of conductive through holes extending from the first surface to the second surface; wherein the plurality of conductive through holes comprise a plurality of first conductive through holes;
a plurality of light-emitting units, disposed on the first surface of the glass substrate; wherein each light-emitting unit comprises an anode, an organic light-emitting layer, and a cathode that are stacked in sequence along a direction away from the glass substrate;
a plurality of first connecting portions; wherein each first connecting portion is disposed within a corresponding first conductive through hole; the first connecting portion is electrically connected to a corresponding anode through the corresponding first conductive through hole;
a silicon-based drive substrate, disposed on a side with the second surface of the glass substrate, and comprising a plurality of first connecting electrodes; wherein each first connecting electrode is at least partially embedded within a corresponding first conductive through hole; and
a plurality of conductive composite layers; wherein each conductive composite layer is disposed between a corresponding first connecting electrode and a corresponding first connecting portion; the corresponding first connecting electrode is electrically connected to the corresponding first connecting portion via the conductive composite layer; the conductive composite layer is capable of breaking an electrical connection between the corresponding first connecting electrode and the corresponding first connecting portion under irradiation of a laser light in a predetermined wavelength band.

18. The display device according to claim 17, wherein the conductive composite layer comprises an excitation member and a response member; the corresponding first connecting electrode is electrically connected to the corresponding first connecting portion via the response member;
the excitation member is configured to provide excitation under the irradiation of the laser light in the predetermined wavelength band; and in response to the excitation provided by the excitation member, the response member is configured to break the electrical connection between the corresponding first connecting electrode and the corresponding first connecting portion.

19. The display device according to claim 18, wherein the excitation member comprises an aerogel layer; the aerogel layer is capable of generating gas under the irradiation of the laser light in the predetermined wavelength band;
the response member comprises a composite repair layer; the composite repair layer comprises a plurality of conductive particles and a plurality of foamed gel particles that are uniformly dispersed; the corresponding first connecting electrode is electrically connected to the corresponding first connecting portion at least partially through the plurality of conductive particles that are uniformly dispersed; the plurality of foamed gel particles are capable of absorbing the gas generated by the aerogel layer;
in response to the plurality of foamed gel particles absorbing the gas generated by the aerogel layer, the plurality of foamed gel particles undergo foaming nucleation growth, causing volume of the plurality of foamed gel particles to expand and compressing the plurality of conductive particles, for causing the plurality of conductive particles to agglomerate and break the electrical connection between the corresponding first connecting electrode and the corresponding first connecting portion.

20. A display panel, comprising:
a glass substrate, comprising a first surface and a second surface that are opposite each other, and defining a plurality of first conductive through holes extending from the first surface to the second surface;
a plurality of light-emitting units, disposed on the first surface of the glass substrate; and
a silicon-based drive substrate, disposed on a side with the second surface of the glass substrate, and comprising a plurality of first connecting electrodes;
wherein for each first conductive through hole, a corresponding light-emitting unit is arranged covering the first conductive through hole, a first connecting portion is arranged in the first conductive through hole and electrically connected to the corresponding light-emitting unit, and a corresponding first connecting electrode is at least partially embedded within the first conductive through hole;
a conductive composite layer is arranged between the corresponding first connecting electrode and the first connecting portion; the corresponding first connecting electrode is electrically connected to the first connecting portion via the conductive composite layer; the conductive composite layer is capable of breaking an electrical connection between the corresponding first connecting electrode and the first connecting portion under irradiation of a laser light in a predetermined wavelength band.
